(19) United States
(12) Patent Application Publication
(10) Pub. No.: US 2009/0236643 A1
(43) Pub. Date: Sep. 24, 2009

(54) CMOS IMAGE SENSOR AND METHOD OF MANUFACTURING

(76) Inventor: Tae-Gyu Kim, Gyeongsangnam-do (KR)

Correspondence Address: SHERR & VAUGHN, PLLC, 620 HERNDON PARKWAY, SUITE 320, HERNDON, VA, 20170, US

(21) Appl. No.: 11/964,474

(22) Filed: Dec. 26, 2007

(30) Foreign Application Priority Data
Dec. 29, 2006 (KR) 10-2006-0137349

(51) Int. Cl. H01L 31/112; H01L 21/60

(52) U.S. Cl. 257/292; 438/98; 257/412; 257/E31.079; 257/E21.506

(57) ABSTRACT

A method of manufacturing an image sensor is capable of preventing image lag and suppressing dark current by performing a substantially perfect reset process. Embodiments relate to a CMOS image sensor which includes a P−-type epi layer which is formed over a semiconductor substrate and defines a photodiode region FD, an active region, and a device isolation region. A device isolation film may be formed in the device isolation region and includes an electrode. A gate electrode may be formed over the P−-type epi layer with a gate insulating film interposed therebetween.

The present application claims priority under 35 U.S.C. 119 to Korean Patent Application No. 10-2006-0137349, filed on 29 Dec. 2006, which is hereby incorporated by reference in its entirety.

### BACKGROUND

An image sensor converts an optical image into an electric signal. Image sensors may be classified as complementary metal oxide silicon (CMOS) image sensors or charge coupled device (CCD) image sensors. A CCD image sensor has relatively higher photosensitivity and lower noise than a CMOS image sensor. However, CCD image sensors are more difficult to miniaturize, and integrate with other devices. Power consumption of the CCD image sensor is also higher. On the other hand, CMOS image sensors are prepared using a simpler process than CCD image sensors. CMOS image sensors are easier to miniaturize, and integrate with other devices. Power consumption of the CCD image sensor is also higher.

With advances in technologies for preparing semiconductor devices, technology for preparing the CMOS image sensors, and consequently the characteristics of the CMOS image sensors, have been greatly improved. Accordingly, much research has been recently carried out on CMOS image sensors.

In a related method of manufacturing a CMOS image sensor, a gap filling process for forming a shallow trench isolation (STI) may cause dislocations due to stress. Undesirable dark currents may occur due to STI etching damage. A densifying process after the gap filling process, or using an ion implantation process, have been used in attempts to solve these problems, and to minimize noise in an STI interface.

Due to characteristics of the CMOS image sensor, noise in the interface between the STI and a photodiode is not negligible in comparison with a saturated signal in an actual image. Thus, a tighter restriction on the noise characteristic is required.

In the CMOS image sensor, to prepare the sensor to detect only genuine image signals, all electrons in a photodiode region are removed using a reset transistor before an image signal is generated. For this purpose, a high V_{dd} would be advantageous for a perfect reset. However, since a CMOS image sensor is typically used in a low-power product such as a mobile telephone, Vdd is restricted. Accordingly, image lag results and the characteristics of the CMOS image sensor are significantly degraded.

### SUMMARY

Embodiments relate to a method of manufacturing an image sensor, which is capable of preventing image lag and suppressing dark current by performing a substantially perfect reset process. Embodiments relate to a CMOS image sensor which includes a P−-type epi layer which is formed over a semiconductor substrate and defines a photodiode region FD, an active region, and a device isolation region. A device isolation film may be formed in the device isolation region and includes an electrode. A gate electrode may be formed over the P−-type epi layer with a gate insulating film interposed therebetween.

Embodiments relate to a method of manufacturing a CMOS image sensor, the method including forming an epi layer, which defines a photodiode region (PD), an active region and a device isolation region, over a semiconductor substrate using an epitaxial process. A gate electrode may be formed having a spacer formed at both sidewalls over the epi layer with a gate insulating film interposed therebetween. A device isolation film may be formed in the device isolation region of the epi layer by a shallow trench isolation (STI) process. A photoresist pattern may be formed for opening a central portion of the device isolation film. A contact hole may be formed in the device isolation film using a reactive ion etching (RIE) method using the photoresist pattern. An electrode may be formed by filling an electrically conductive material in the contact hole.

In embodiments, the contact hole of the device isolation film may be formed by a depth corresponding to between approximately ½ and ⅔ of that of the device isolation film. In embodiments, the forming of the electrode may include filling the contact hole with metal or polysilicon, performing an etch-back process, and planarizing the metal or polysilicon.

### DRAWINGS

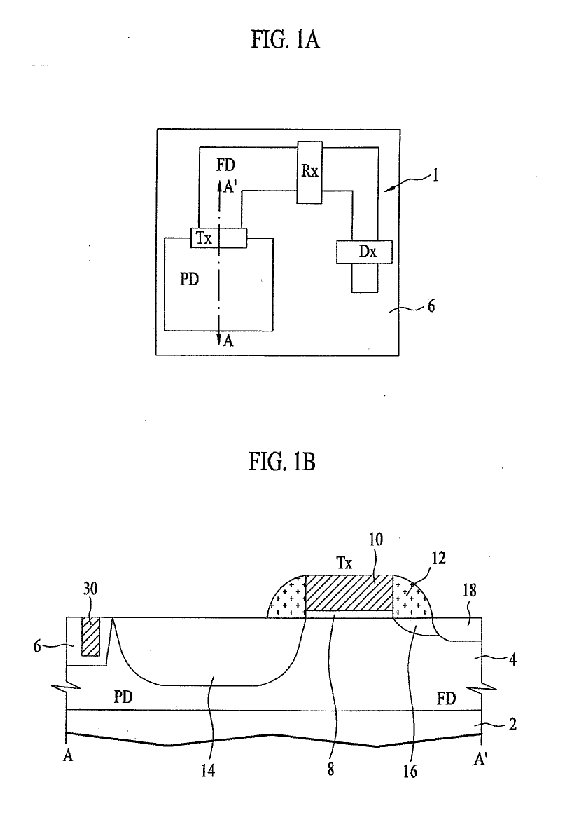

Example FIG. 1A is a plan view showing a CMOS image sensor according to embodiments.

Example FIG. 1B is a cross-sectional view taken along line A-A′ of example FIG. 1A.

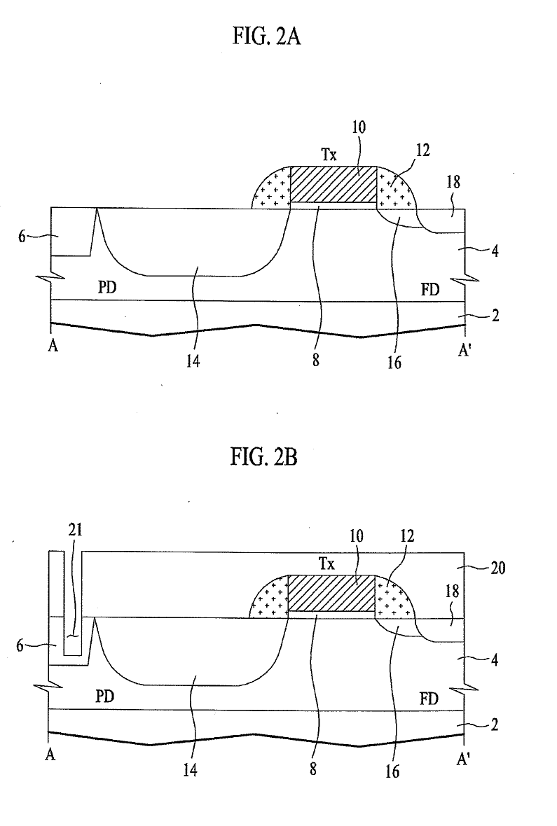

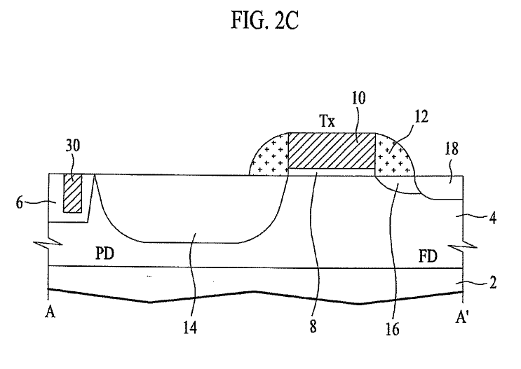

Example FIGS. 2A to 2C are cross-sectional views illustrating a method of manufacturing a CMOS image sensor according to embodiments.

### DESCRIPTION

Example FIG. 1A is a plan view showing a CMOS image sensor according to embodiments, example FIG. 1B is a cross-sectional view taken along line A-A′ of example FIG. 1A, and example FIGS. 2A to 2C are cross-sectional views illustrating a method of manufacturing a CMOS image sensor according to embodiments.

As shown in example FIGS. 1A and 1B, the CMOS image sensor according to embodiments includes a photodiode region PD which may be formed at a widest portion in an active region 1, a transfer transistor Tx which is formed to overlap the active region 1 excluding the photodiode region PD, a reset transistor Rx, and a drive transistor Dx. The CMOS image sensor includes a P+-type semiconductor substrate 2 in which the photodiode region PD, the active region 1 and a device isolation region may be defined. A P−-type epi layer 4 may be formed over the semiconductor substrate 2. A device isolation film 6 may be formed in the device isolation region and including an electrode 30 formed therein. A gate electrode 10 may be formed over the epi layer 4 with a gate insulating film 8 interposed therebetween. An n−-type diffusion region 14 may be formed in the epi layer 4 of the photodiode region PD. A gate spacer 12 may be formed at both sidewalls of the gate electrode 10. A lightly doped drain (LDD) region 16 may be formed in the active region 1 among the transistors Tx, Rx and Dx. An n+-type diffusion region 18 may be formed by implanting n+-type dopant ions into the epi layer 4 of a floating diffusion region FD.

Since the CMOS image sensor with the above-described structure has electrode 30 formed of an electrically conductive material such as metal or polysilicon in the device isolation film 6, a bias may be applied through the electrode 30 to adjust the voltage of the photodiode region PD such that a substantially perfect reset is implemented. When an image signal is output, dark current which occurs in an interface of the device isolation film 6 is suppressed, thereby improving image characteristics.

In particular, if V_{dd} is applied to the floating diffusion region FD through the reset transistor Rx when a reset function is performed, electrons in the photodiode region PD flow toward the drain of the transistor Rx. At this time, when a backward bias is applied through a contact connected to the electrode 30, a voltage difference between the floating diffusion region FD and the photodiode region PD increases such that the electrons may be rapidly and substantially perfectly reset through the floating diffusion region FD.

When the image signal is output, electrons, which are generated in the photodiode region FD by photoelectric effect, drop a gate voltage of the drive transistor Dx through the floating diffusion region FD. At this time, when a voltage is applied to the electrode 30 of the device isolation film 6, leakage current which occurs in the interface of the device isolation film 6 may be prevented from mixing with the image signal.

In a high-speed image process, when an image signal is output, a backward bias may be applied to the electrode 30 of a device isolation film 6. Electrons are rapidly and substantially perfectly moved to the floating diffusion region (FD), similar to a case where a reset function is performed. Thus, the signal can be substantially perfectly output with a higher speed.

Accordingly, a voltage is applied to the electrode 30 of the device isolation film 6 to more rapidly perform the reset function. Leakage current at the interface of the device isolation film 6 is also prevented from mixing with an image signal. Also, a faster image process may be performed, such that image lag is prevented and dark currents are minimized to improve image characteristics.

Hereinafter, a method of manufacturing the CMOS image sensor having the above-described structure will be described with reference to example FIGS. 2A to 2C. As shown in example FIG. 2A, the P−-type epi layer 4 may be formed over the P+-type semiconductor substrate 2 using an epitaxial process. Gate electrode 10, including the spacer 12 formed at the both sidewalls, may be formed over the P−-type epi layer 4 with the gate insulating film 8 interposed therebetween. N−-type diffusion region 14 and the LDD region 16 may be formed by implanting and diffusing n−-type dopant between the gate electrode 10 and the device isolation film 6.

After device isolation film 6 is formed in the P−-type epi layer 4, as shown in example FIG. 2B, a photoresist pattern 20 for opening a central portion of the device isolation film 6 is formed. The contact hole 21 may be formed to a depth corresponding to between approximately ½ and ⅔ of that of the device isolation film 6 using a RIE method using the photoresist pattern 20.

The contact hole 21 may be filled with an electrically conductive material such as metal or polysilicon. An ashing process may be performed to remove the photoresist pattern 20. The metal or polysilicon may be planarized using an etch-back process, such that the resulting electrode 30 is formed in the device isolation film 6, as shown in example FIG. 2C.

Thereafter, an interlayer insulating film is formed over the device isolation film 6 and the gate electrode 10. A contact may be formed in the interlayer insulating film and connected to the electrode 30 in the device isolation film 6. A backward bias may be applied through the contact connected to the electrode 30 to increase a voltage difference between the floating diffusion region FD and the photodiode region PD such that electrons can be rapidly and substantially perfectly moved through the floating diffusion region FD.

As described above, by applying a voltage to an electrode in a device isolation film, it is possible to provide a CMOS image sensor capable of substantially preventing leakage current at the interface of the device isolation film from becoming mixed with an image signal. It is also possible to minimize image lag by minimizing dark current, and improving image characteristics.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a P−-type epi layer, having defined therein a photodiode region, an active region, and a device isolation region, the P−-type epi layer formed over a semiconductor substrate;
a device isolation film formed in the device isolation region;
an electrode formed in the device isolation film.

2. The apparatus of claim 1, wherein the electrode is formed to a depth corresponding to between approximately ½ and ⅔ of that of the device isolation film.

3. The apparatus of claim 1, wherein the electrode is formed of an electrically conductive material.

4. The apparatus of claim 3, wherein the electrode is formed of metal.

5. The apparatus of claim 3, wherein the electrode is formed of polysilicon.

6. The apparatus of claim 1, comprising a contact connected to the electrode.

7. The apparatus of claim 1, wherein a backward bias is applied to the contact connected to the electrode to increase a voltage difference between a floating diffusion region and the photodiode region such that electrons in the photodiode region are moved through the floating diffusion region to perform a reset process.

8. The apparatus of claim 1, wherein a backward bias is applied to a contact connected to the electrode to prevent leakage current, which occurs in an interface of the device isolation film, from becoming mixed with an image signal.

9. The apparatus of claim 1 comprising:
a gate insulating film formed over the P−-type epi layer; and
a gate electrode formed over said gate insulating layer.

10. The apparatus of claim 9 comprising spacers formed over sidewalls of the gate electrode.

11. A method comprising:
forming an epi layer, which defines a photodiode region, an active region and a device isolation region, over a semiconductor substrate using an epitaxial process;
forming a device isolation film in the device isolation region of the epi layer using a shallow trench isolation process;
forming a photoresist pattern for opening a central portion of the device isolation film;
forming a contact hole in the device isolation film using a reactive ion etching method using the photoresist pattern; and
forming an electrode by filling the contact hole with an electrically conductive material.

12. The method of claim 11, wherein the electrically conductive material is metal.

13. The method of claim 11, wherein the electrically conductive material is polysilicon.

14. The method of claim 11, comprising forming a gate insulating film over the epi layer.

15. The method of claim 14, comprising forming a gate electrode over the gate insulating film.

16. The method of claim 15, comprising forming a spacer over sidewalls of the gate.

17. The method of claim 16, comprising forming an interlayer insulating film over the device isolation film and the gate electrode.

18. The method of claim 17, comprising forming a contact electrically connected to the electrode in the interlayer insulating film.

19. The method of claim 11, wherein the contact hole of the device isolation film is formed to a depth corresponding to between approximately ½ and ⅔ of that of the device isolation film.

20. The method of claim 11, comprising performing an etch-back process to planarize the electrically conductive material.
